(19) United States
(12) Patent Application Publication
(10) Pub. No.: US 2014/0273484 A1
(43) Pub. Date: Sep. 18, 2014

(54) INDUCTIVELY COUPLED PLASMA PROCESSING APPARATUS AND PLASMA PROCESSING METHOD USING THE SAME

(71) Applicant: SAMSUNG ELECTRONICS CO., LTD., Suwon-si (KR)

(72) Inventors: JEONG-YUN LEE, YONGIN-SI (KR); HAE-JOONG PARK, SUWON-SI (KR); KYUNG-YUB JEON, YONGIN-SI (KR); SANG-JEAN JEON, HWASEONG-SI (KR)

(73) Assignee: SAMSUNG ELECTRONICS CO., LTD., Suwon-si (KR)

(21) Appl. No.: 14/200,978

(22) Filed: Mar. 7, 2014

(30) Foreign Application Priority Data
Mar. 14, 2013 (KR) 10-2013-0027113

(51) Int. Cl. H01L 21/3065; H01L 21/67

(52) U.S. Cl. CPC H01L 21/3065; H01L 21/67069
USPC 438/710; 156/345.38; 156/345.28; 156/345.47

(57) ABSTRACT

An inductively coupled plasma processing apparatus includes a chamber configured to provide a space for processing a substrate and including a window formed in an upper portion thereof, a substrate stage configured to support the substrate within the chamber and including a lower electrode, the lower electrode configured to receive a first radio frequency signal, an upper electrode arranged on the upper portion of the chamber with the window interposed between the upper electrode and the space for processing the substrate, the upper electrode configured to receive a second radio frequency signal, a conductive shield member arranged within the chamber and configured to cover the window, and a shield power supply configured to apply a shield signal to the shield member in synchronization with the second radio frequency signal.

### PRIORITY STATEMENT

A claim of priority under 35 U.S.C. §119 is made to Korean Patent Application No. 10-2013-0027113, filed on Mar. 14, 2013 in the Korean Intellectual Property Office (KIPO), the contents of which are herein incorporated by reference in their entirety.

### BACKGROUND

Example embodiments relate to plasma processing. More particularly, example embodiments relate to inductively coupled plasma processing apparatus and to plasma processing methods using inductively couple plasma apparatus.

In the manufacture of semiconductor devices and flat panel display devices, as examples, a plasma processing apparatus may be used in a variety of different fabrication processes such etching, deposition, oxidation, sputtering and the like. In the case of inductively coupled plasma processing, a radio frequency power is applied to an antenna arranged on a window in an upper wall of a chamber, and an electric field is generated within the chamber via the window. In an etching process, for example, the electric field ionizes an etching gas to form a plasma within the chamber.

Etching within the plasma processing chamber can result in by-products being deposited on chamber walls and the chamber window. For example, when fabricating a magnetic tunnel junction (MTJ) for a magneto-resistive random access memory (MRAM) device, a material layer which may include a metal material (for example, Ru, Ti, Ta, Co, Fe, Pd, Pt, etc.) is etched in the plasma apparatus. Process by-products such as high dielectric materials and/or conductive material may be deposited on the sidewalls and window of the chamber, which can potentially inhibit generation of the plasma forming electric field. It is thus necessary to periodically clean the chamber, which slows production.

### SUMMARY

According to example embodiments, an inductively coupled plasma processing apparatus includes a chamber configured to provide a space for processing a substrate and including a window formed in an upper portion thereof, a substrate stage configured to support the substrate within the chamber and including a lower electrode, the lower electrode configured to receive a first radio frequency signal, an upper electrode arranged on the upper portion of the chamber with the window interposed between the upper electrode and the space for processing the substrate, the upper electrode configured to receive a second radio frequency signal, a conductive shield member arranged within the chamber and configured to cover the window, and a shield power supply configured to apply a shield signal to the shield member in synchronization with the second radio frequency signal.

The second radio frequency signal may be a pulse signal with each pulse having an ON period and an OFF period, and the shield signal may be a pulse signal with each pulse having an ON period contained within the OFF period of the second radio frequency signal.

The shield signal may be AC power or DC power.

The shield member may include a plurality of slits configured to pass there through a magnetic field generated by the upper electrode into the chamber.

The window may include an insulating material.

The apparatus may further include a gas supply unit in fluid communication with the chamber, and a gas exhaust unit in fluid communication with the chamber.

The apparatus may further include a first radio frequency power supply configured to apply the first radio frequency signal to the lower electrode, and a second radio frequency power supply configured to apply the second radio frequency signal to the upper electrode. The apparatus may still further include a control unit configured to control the shield power supply and the second radio frequency power supply so that the second radio frequency control signal and the shield signal are synchronized with each other.

The apparatus may be configured to perform a plasma etching process on the substrate to form a magnetic pattern having a magnetic tunnel junction structure on the substrate.

According to other example embodiments, an inductively couple plasma processing apparatus includes a chamber including a window defined in an upper portion thereof, an upper electrode external the chamber adjacent the window, a substrate support in the chamber, and a lower electrode in the chamber. The processing apparatus further includes a conductive shield member located over the window within the chamber, a shield power supply configured to supply a pulsed shield signal to the shield member, and a radio frequency (RF) power supply configured to supply a pulsed RF signal to the upper electrode.

The apparatus may further include a control unit configured to control the shield power supply and the RF power supply such that an ON period of each pulse of the pulsed shield signal is contained within an OFF period of each pulse of the pulsed RF signal.

The pulsed shield signal may a DC pulse signal or an AC pulse signal.

According to still other example embodiments, a plasma processing method includes loading a substrate into a chamber of an inductively coupled plasma process apparatus, the inductively coupled plasma process apparatus including the chamber including a window in an upper portion thereof, a substrate stage configured to support the substrate within the chamber and including a lower electrode, an upper electrode located on the upper portion of the chamber with the window interposed between the upper electrode and the lower electrode, and a conductive shield member arranged within the chamber to cover the window. The method further includes introducing a process gas into the chamber, applying first and second radio frequency signals to the lower electrode and the upper electrode respectively to perform a plasma process on the substrate, and applying a shield signal to the conductive shield member during the plasma process, the shield signal being synchronized with the second radio frequency signal.

The second radio frequency signal may be a pulse signal having an ON period and OFF period, and the shield signal may be a pulse signal having an ON period contained within the OFF period of the second radio frequency signal.

The shield signal may be an AC power pulsed signal or a DC power pulsed signal.

The introducing the process gas into the chamber may include supplying an etching gas into the chamber, and the method may further include exhausting a gas from the chamber to control a pressure of the chamber to a given vacuum level.

### BRIEF DESCRIPTION OF THE DRAWINGS

Example embodiments will become understood from the detailed description that follows, with reference to the accompanying drawings. These drawings represent non-limiting, example embodiments as described herein.

FIG. 1 is a diagram illustrating a plasma processing apparatus in accordance with example embodiments.

FIG. 2 is a block diagram illustrating an example of a controller of the plasma processing apparatus in FIG. 1.

FIGS. 3 and 4 are waveform diagrams illustrating examples of a synchronized relationship between respective signals applied to an upper electrode and to a conductive shield member of the plasma processing apparatus in FIG. 1.

FIG. 5 is a flow chart for reference in describing a plasma processing method in accordance with example embodiments.

### DETAILED DESCRIPTION OF EXAMPLE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

FIG. 1 is a combined cross-sectional view and block diagram illustrating a plasma processing apparatus in accordance with example embodiments. FIG. 2 is a block diagram illustrating an example of a controller of the plasma processing apparatus in FIG. 1. FIGS. 3 and 4 are waveform diagrams illustrating examples of a synchronized relationship between respective signals applied to an electrode and to a conductive shield member of the plasma processing apparatus in FIG. 1.

Referring to FIGS. 1 to 4, a plasma processing apparatus 100 may include a chamber 110, a substrate stage 120 having a lower electrode 124, an upper electrode 140, a conductive shield member 200, and a shield power supply 210.

In example embodiments, the plasma processing apparatus may be configured as an inductively coupled plasma (ICP) etching apparatus. The chamber 110 may provide a sealed space where a plasma process is performed on a substrate.

The substrate stage 120 may be arranged in the chamber 110. For example, the substrate stage 120 may include the lower electrode 124 that serves as a susceptor for supporting a semiconductor wafer (W) thereon. The lower electrode 124 may be circular plate-shaped, and may be supported by a support member 122 such that the lower electrode 124 is movable in upward and downward direction.

A gas exhaust port 114 may be provided in a bottom portion of the chamber 110. A gas exhaust unit 118 may be in fluid communication with the gas exhaust port 114 through a gas exhaust line 116. The gas exhaust unit 118 may include a vacuum pump such as a turbo-molecular pump or the like, to control the pressure of the chamber 110 so that the processing space inside the chamber 110 may be depressurized to a desired vacuum level. A gate 112 for opening and closing a loading/unloading port of the semiconductor wafer (W) may be provided in a sidewall of the chamber 110.

An electrostatic chuck 126 for adsorbing a wafer may be provided on an upper surface of the lower electrode 124. The electrostatic chuck 126 may include a dielectric layer and a conductor sealed in the dielectric layer. The dielectric layer of the electrostatic chuck may have a film shape or a plate shape. The conductor of the electrostatic chuck may have a sheet shape or a mesh shape. The semiconductor wafer (W) may be adsorptively held on the electrostatic chuck 126 when a direct current is applied to the conductor by a DC power source (not illustrated).

The semiconductor wafer (W) may be mounted on the upper surface of the lower electrode 124, and a focus ring 128 may be installed to surround the semiconductor wafer (W). The lower electrode 124 may have a diameter which is greater than a diameter of the semiconductor wafer (W). The lower electrode 124 may have a cooling channel (not illustrated) therein. In order to increase a control accuracy of the semiconductor wafer (W), a heat transfer gas such as a He gas may be supplied to a gap between the electrostatic chuck 126 and the semiconductor wafer (W).

A window 130 may be provided in an upper portion of the chamber 110. The window 130 may constitute a part or an entirety of the upper portion of the chamber 110. For example, the window 130 may include an insulating material such as alumina (Al₂O₃). The plasma processing apparatus 100 may further include a gas supply unit 160 in fluid communication with the chamber 110 via a gas supply line 162. A process gas may be supplied to the chamber 110 through the gas supply line 162 from the gas supply unit 160.

The upper electrode 140 may be provided on the window 130 outside the chamber 110 such that the upper electrode 140 faces towards the lower electrode 124. The upper electrode 140 may include a radio frequency antenna. The radio frequency antenna may be an inductively coupled antenna.

The plasma processing apparatus 100 may further include a first radio frequency power supply 150 for applying a first radio frequency signal to the lower electrode 124, and a second radio frequency power supply 152 for applying a second radio frequency signal to the upper electrode 140. Although not shown, the first radio frequency power supply 150 may include a first radio frequency power source and a first impedance matching circuit, and the second radio frequency power supply 152 may include a second radio frequency power source and a second impedance matching circuit.

The plasma processing apparatus 100 may include a control unit 300 for controlling the first and second radio frequency power supplies 150 and 152. The control unit 300, which includes a microcomputer and various interface circuits, may control an operation of the plasma process apparatus 100 based on programs and recipe information stored in an external or internal memory.

The control unit 300 may include a first signal generator 310 for generating a first radio frequency control signal and a second signal generator 320 for generating a second radio frequency control signal.

The first radio frequency power supply 150 is connected to the first signal generator 310 to receive the first radio frequency control signal from the first signal generator 310. The first radio frequency power supply 150 may generate and apply the first radio frequency signal to the lower electrode 124 in response to the first radio frequency control signal inputted from the first signal generator 310. The second radio frequency power supply 152 is connected to the second signal generator 320 to receive the second radio frequency control signal from the second signal generator 320. The second radio frequency power supply 152 may generate and apply the second radio frequency signal to the upper electrode 140 in response to the second radio frequency control signal inputted from the second signal generator 320.

Each of the first and second radio frequency signals may include a radio frequency power having a predetermined frequency (for example, 13.56 MHz). Each of the first and second radio frequency signals may include a radio frequency pulse signal having an ON period and an OFF period. The first and second radio frequency signals respectively applied to the lower electrode 124 and the upper electrode 140 may have a same phase or may be offset by a predetermined phase difference.

In example embodiments, the conductive shield member 200 may be arranged in the chamber 110 to cover the window 130. The conductive shield member 200 may have a shape corresponding to the window 130. For example, when the window 130 has a circular plate shape, the conductive shield member 200 may have a circular plate shape.

The conductive shield member 200 may be detachably installed in the upper portion of the chamber 110. The conductive shield member 200 may act as a shield to prevent or inhibit process by-products from being deposited on an inner wall of the window 130. When an excessive amount of by-products are deposited on the conductive shield member 200, the conductive shield member 200 may be detached from the chamber 110 to be cleaned, and then, may be installed again on the window 130.

The shield power supply 210 may be connected to the conductive shield member 200 to apply a shield signal to the shield member 200. The shield signal may be synchronized with the second radio frequency signal, i.e., the radio frequency signal applied to the upper electrode 140. The shield signal may include AC power or DC power. The AC power or the DC power may be applied to the conductive shield member 200 to generate an electric field over the shield member 200.

The conductive shield member 200 may have a plurality of slits 202 for passing there through a magnetic field generated by the upper electrode 140 to the chamber 110. The conductive shield member 200 may include or be made of a metal such as aluminum.

As illustrated in FIG. 2, the second signal generator 320 of the control unit 300 may include a second radio frequency signal generator 322 and a shield signal generator 324. The second radio frequency signal generator 322 may generate the second radio frequency control signal, and the shield signal generator 324 may generate a shield control signal which is synchronized with the second radio frequency control signal. The shield power supply 210 is connected to the shield signal generator 324 of the second signal generator 320 to receive the shield control signal from the shield signal generator 324. The shield power supply 210 may generate and apply the shield signal to the shield member 200 in response to the shield control signal inputted from the shield signal generator 324.

The shield signal may be a signal having a relatively high voltage and low current. The shield signal may be a pulse signal synchronized with the second radio frequency signal applied to the upper electrode 140. The shield signal applied to the shield member 200 may have a predetermined phase difference with respect to the second high radio frequency signal applied to the upper electrode 140. The shield signal may include a pulse signal having a specific level at a predetermined period between a start time and an end time of an OFF period of the second high radio frequency signal.

For example, the shield signal may be maintained in an ON state within the OFF period of the second radio frequency signal. Alternatively, the shield signal may be a pulse signal having high level and low level. In this case, the shield signal may be maintained to have a high level within an ON period of the second radio frequency signal and to have a low level within an OFF period of the second radio frequency signal.

FIGS. 3 and 4 are graphs illustrating a timing of the radio frequency signal applied to the upper electrode and a timing of the shield signal applied to the conductive shield member.

Referring to FIG. 3, when a voltage (Vrf) of the radio frequency signal applied to the upper electrode 140 is in ON state, a voltage (Vs) of the shield signal applied to the conductive shield member 200 may be in OFF state. The voltage (Vs) of the shield signal may be in ON state at a predetermined period within OFF period of the voltage (Vrf) of the radio frequency signal.

The shield signal may include AC power synchronized with the second radio frequency. The shield signal synchronized with the second radio frequency may be applied to the shield member 200. The shield signal may be timed such that the shield signal may be applied to the shield member 200 within the OFF period of the second radio frequency signal.

Referring to FIG. 4, the shield signal applied to the conductive shield member 200 may include DC power. A voltage (Vs) of the shield signal may be in an ON state within the OFF period of a voltage (Vrf) of the radio frequency signal applied to the upper electrode 140.

As mentioned above, the shield signal applied to the conductive shield member 200 may be synchronized with the second radio frequency signal applied to the upper electrode 140. The shield signal may be selectively applied to the shield member 200 within OFF period of the second radio frequency signal.

Accordingly, during a plasma process, the shield signal having a synchronization relationship with respect to the second radio frequency signal may be applied to the shield member 200 to generate an electric field over the shield member 200 such that process by-products may be inhibited from being deposited on the window 130 that define at least a portion of an upper wall of the chamber 110 and a deposited material layer may be removed. Further, the shield signal may be applied to the shield member 200 within the OFF period of the source power, to thereby prevent generation of arcing and interference with a coil antenna. Thus, equipment repair and maintenance for a plasma chamber may be optimized and damage caused to the chamber by performing the plasma process may be reduced.

Hereinafter, a method of processing a substrate using the plasma processing apparatus in FIG. 1 will be explained.

FIG. 5 is a flow chart illustrating a plasma processing method in accordance with example embodiments.

Referring to FIGS. 1, 2 and 5, after a substrate is loaded into an inductively coupled plasma chamber 110 (S100), a process gas may be supplied onto the substrate (S110).

First, a semiconductor wafer (W) may be loaded on an electrostatic chuck 126 in the chamber 110 through a gate 112. A process gas (for example, an etching gas) may be introduced into the chamber 110 from a gas supply unit 160 and then a pressure of the chamber 110 may be controlled to a desired vacuum level by a gas exhaust unit 118.

Then, first and second radio frequency signals may be applied to a lower electrode 124 and an upper electrode 140 such that a plasma process may be performed on the semiconductor wafer (W) (S120).

A first radio frequency power supply 150 may supply a first radio frequency signal for bias control to a lower electrode 124 and a second radio frequency power supply 152 may supply a second radio frequency signal for plasma generation to an upper electrode 140, in response to a control signal of a control unit 300.

In here, each of the first and second radio frequency signals may be a pulse signal having an ON period and an OFF period. The first and second radio frequency signals have a same phase or a predetermined phase difference with respect to each other may be applied to the lower electrode 124 and the upper electrode 140 respectively.

The etching gas discharged from the upper electrode 140 may be converted into a plasma between the lower electrode 124 and the upper electrode 140 by a radio frequency discharge, and a target layer on the semiconductor wafer (W) may be etched to have a desired pattern by radicals or ions generated from the plasma. For example, magnetic material layers on the semiconductor wafer (W) may be etched to form a magnetic pattern having a magnetic tunnel junction (MTJ) structure by a plasma etching process.

Then, during performing the plasma process, a shield signal synchronized with the second radio frequency signal may be applied to a conductive shield member 200 (S 130).

As illustrated in FIG. 2, a second signal generator 320 of the control unit 300 may include a second radio frequency signal generator 322 and a shield signal generator 324. The second radio frequency signal generator 322 may generate a second radio frequency control signal, and the shield signal generator 324 may generate a shield control signal which is synchronized with the second radio frequency control signal. A shield power supply 210 may apply the shield signal to the shield member 200 in response to the shield control signal inputted from the shield signal generator 324.

The shield signal may be a signal having a relatively high voltage and low current. The shield signal may be a pulse signal synchronized with the second radio frequency signal. The shield signal having a predetermined phase difference with respect to the second high radio frequency signal may be applied to the shield member 200. For example, the shield signal may have an ON period within an OFF period of the second radio frequency signal.

As mentioned above, the shield signal applied to the conductive shield member 200 may be synchronized with the second radio frequency signal applied to the upper electrode 140. The shield signal may be selectively applied to the shield member 200 within the OFF period of the second radio frequency signal.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An inductively coupled plasma processing apparatus, comprising:
a chamber configured to provide a space for processing a substrate and including a window formed in an upper portion thereof;
a substrate stage configured to support the substrate within the chamber and including a lower electrode, the lower electrode configured to receive a first radio frequency signal;
an upper electrode arranged on the upper portion of the chamber with the window interposed between the upper electrode and the space for processing the substrate, the upper electrode configured to receive a second radio frequency signal;
a conductive shield member arranged within the chamber and configured to cover the window; and
a shield power supply configured to apply a shield signal to the shield member in synchronization with the second radio frequency signal.

2. The inductively coupled plasma processing apparatus of claim 1, wherein the second radio frequency signal is a pulse signal with each pulse having an ON period and an OFF period, and the shield signal is a pulse signal with each pulse having an ON period contained within the OFF period of the second radio frequency signal.

3. The inductively coupled plasma processing apparatus of claim 1, wherein the shield signal comprises AC power.

4. The inductively coupled plasma processing apparatus of claim 1, wherein the shield signal comprises DC power.

5. The inductively coupled plasma processing apparatus of claim 1, wherein the shield member comprises a plurality of slits configured to pass there through a magnetic field generated by the upper electrode into the chamber.

6. The inductively coupled plasma processing apparatus of claim 1, wherein the window comprises an insulating material.

7. The inductively coupled plasma processing apparatus of claim 1, further comprising a gas supply unit in fluid communication with the chamber.

8. The inductively coupled plasma processing apparatus of claim 1, further comprising a gas exhaust unit in fluid communication with the chamber.

9. The inductively coupled plasma processing apparatus of claim 1, further comprising a first radio frequency power supply configured to apply the first radio frequency signal to the lower electrode, and a second radio frequency power supply configured to apply the second radio frequency signal to the upper electrode.

10. The inductively coupled plasma processing apparatus of claim 9, further comprising a control unit configured to control the shield power supply and the second radio frequency power supply so that the second radio frequency control signal and the shield signal are synchronized with each other.

11. The inductively coupled plasma processing apparatus of claim 1, wherein the apparatus is configured to perform a plasma etching process on the substrate to form a magnetic pattern having a magnetic tunnel junction structure on the substrate.

12. An inductively couple plasma processing apparatus, comprising a chamber including a window defined in an upper portion thereof, an upper electrode external the chamber adjacent the window, a substrate support in the chamber, and a lower electrode in the chamber, the processing apparatus further comprising:
a conductive shield member located over the window within the chamber, a shield power supply configured to supply a pulsed shield signal to the shield member, and a radio frequency (RF) power supply configured to supply a pulsed RF signal to the upper electrode.

13. The inductively coupled plasma processing apparatus of claim 12, further comprising a control unit configured to control the shield power supply and the RF power supply such that an ON period of each pulse of the pulsed shield signal is contained within an OFF period of each pulse of the pulsed RF signal.

14. The inductively coupled plasma processing apparatus of claim 13, wherein the pulsed shield signal is a DC pulse signal.

15. The inductively coupled plasma processing apparatus of claim 13, wherein the pulsed shield signal is an AC pulse signal.

16. A plasma processing method, comprising:
loading a substrate into a chamber of an inductively coupled plasma process apparatus, the inductively coupled plasma process apparatus comprising the chamber including a window in an upper portion thereof, a substrate stage configured to support the substrate within the chamber and including a lower electrode, an upper electrode located on the upper portion of the chamber with the window interposed between the upper electrode and the lower electrode, and a conductive shield member arranged within the chamber to cover the window;
introducing a process gas into the chamber;
applying first and second radio frequency signals to the lower electrode and the upper electrode respectively to perform a plasma process on the substrate; and
applying a shield signal to the conductive shield member during the plasma process, the shield signal being synchronized with the second radio frequency signal.

17. The method of claim 11, wherein the second radio frequency signal is a pulse signal having an ON period and OFF period, and the shield signal is a pulse signal having an ON period contained within the OFF period of the second radio frequency signal.

18. The method of claim 11, wherein the shield signal is an AC power pulsed signal or a DC power pulsed signal.

19. The method of claim 11, wherein introducing the process gas into the chamber comprises supplying an etching gas into the chamber.

20. The method of claim 11, further comprising exhausting a gas from the chamber to control a pressure of the chamber to a given vacuum level.
